(19) United States
(12) Patent Application Publication
(10) Pub. No.: US 2025/0393239 A1
(43) Pub. Date: Dec. 25, 2025

(54) GATE-ALL-AROUND TRANSISTOR AND METHOD FOR MANUFACTURING THE SAME

(71) Applicant: INSTITUTE OF MICROELECTRONICS, CHINESE ACADEMY OF SCIENCES, Beijing (CN)

(72) Inventors: Qingzhu Zhang, Beijing (CN); Meihe Zhang, Beijing (CN); Xinghua Wang, Beijing (CN); Lianlian Li, Beijing (CN); Lei Cao, Beijing (CN); Qingkun Li, Beijing (CN); Guanqiao Sang, Beijing (CN); Renjie Jiang, Beijing (CN); Peng Wang, Beijing (CN)

(21) Appl. No.: 19/088,387

(22) Filed: Mar. 24, 2025

(30) Foreign Application Priority Data
Jun. 24, 2024 (CN) 202410818112.1

(51) Int. Cl. H10D 30/00; H10D 30/01; H10D 30/43; H10D 62/10; H10D 64/01; H10D 64/27

(52) U.S. Cl. CPC H10D 30/502; H10D 30/014; H10D 30/0191; H10D 30/43; H10D 62/102; H10D 62/121; H10D 64/017; H10D 64/021; H10D 64/516; H10D 64/518

(57) ABSTRACT

A gate-all-around transistor, comprising: a semiconductor substrate, where a fin-shaped protrusion is provided at a surface of the semiconductor substrate on one side; a source and a drain arranged on the top surface of the fin-shaped protrusion, respectively; a gate comprising a first gate part on the top surface of the fin-shaped protrusion between the source and the drain and a second gate part on a surface of the first gate part on the side away from the fin-shaped protrusion; a first dielectric layer on two opposite sides of the first gate part in a first direction; a second dielectric layer on two opposite sides of the second gate part in the first direction; where: the first direction is parallel to the direction of connecting the source and the drain; a dielectric constant of the first dielectric layer is greater than that of the second dielectric layer.

This application claims priority to Chinese Patent Application No. 202410818112.1, titled “GATE-ALL-AROUND TRANSISTOR AND METHOD FOR MANUFACTURING THE SAME”, filed on Jun. 24, 2024 with the China National Intellectual Property Administration, which is incorporated herein by reference in its entirety.

### FIELD

The present disclosure relates to the technical field of semiconductor device, and in particular to a gate-all-around transistor and a method for manufacturing the same.

### BACKGROUND

As an integrated circuit being continuously miniaturized, conventional planar metal oxide semiconductor field effect transistor (MOSFET) has large leakage current and power consumption due to the size effect of the integrated circuit, such that the normal operation of the circuit is significantly influenced. Fin field effect transistor (FinFET), as an alternative for the MOSFET, has also been miniaturized to the physical limit for the structure of the FinFET, at which the performance of the FinFET has been deteriorated. Gate-All-Around FET (GAA FET) has become an important structure for achieving the technology node with 3 nm or below, due to its advantages of optimal gate control performance, higher carrier ballistic transport efficiency and less device process fluctuation and so on.

The gate-all-around transistor is mainly distinguished from a conventional transistor by a unique structure of a gate of the gate-all-around transistor. In the gate-all-around transistor, a channel of the gate-all-around transistor is surrounded by the gate all around. This structure significantly increases the contact area between the gate and the channel, allowing a better control to the channel. With this gate-all-around design, not only the performance of the transistor is improved, but also parasitic capacitance and resistance problems are effectively alleviated, making this structure have obvious advantages at the technology node with 3 nm and the following technology nodes.

### SUMMARY

In view of the above problems, the present disclosure provides a gate-all-around transistor and a method for manufacturing the gate-all-around transistor, and the specific aspects of the present disclosure are as follows:

A first aspect of the present disclosure provides a gate-all-around transistor comprising: a semiconductor substrate, where a fin-shaped protrusion is provided at a surface of the semiconductor substrate on one side; a source and a drain arranged on a top surface of the fin-shaped protrusion, respectively; a gate comprising a first gate part and a second gate part; the first gate part being located on the top surface of the fin-shaped protrusion between the source and the drain; the second gate part being located on a surface of the first gate part on the side away from the fin-shaped protrusion; a first dielectric layer on two opposite sides of the first gate part in a first direction; a second dielectric layer on two opposite sides of the second gate part in the first direction; where the first direction is parallel to a direction of connecting the source and the drain; a dielectric constant of the first dielectric layer is greater than a dielectric constant of the second dielectric layer.

Optionally, the first gate part may comprise a plurality of gate blocks stacked in sequence in a second direction, and the second direction is parallel to a height direction of the fin-shaped protrusion; the gate-all-around transistor may further comprise a first semiconductor layer between adjacent gate blocks; two opposite sides of the first semiconductor layer may contact the source and the drain on in the first direction; the plurality of gate blocks may be spaced apart from both the source and the drain for receiving the first dielectric layer.

Optionally, a gate dielectric layer may be disposed between the plurality of gate blocks and the first semiconductor layer and between the plurality of gate blocks and the first dielectric layer; the gate dielectric layer may be disposed between the second gate part and the second dielectric layer; where a dielectric constant of the gate dielectric layer is greater than the dielectric constant of the second dielectric layer.

Optionally, the dielectric constant of the gate dielectric layer may be greater than the dielectric constant of the first dielectric layer.

Optionally, a thickness of the gate dielectric layer may be smaller than a thickness of the first dielectric layer and smaller than a thickness of the second dielectric layer.

Optionally, in the first direction, a length of the first gate part is identical with a length of the second gate part, sides of the first gate part and the second gate part are aligned in the second direction, and the thicknesses of the first dielectric layer is identical with the thicknesses of the second dielectric layer.

Optionally, in the first direction, a length of the first gate part is different from a length of the second gate part, sides of the first gate part and the second gate part are not aligned in the second direction, and the thicknesses of the first dielectric layer is different from the thickness of the second dielectric layer.

Optionally, in the first direction, the length of the first gate part is greater than the length of the second gate part, a side of the second gate part is retracted relative to a side of the first gate part, and the thickness of the first dielectric layer is less than the thickness of the second dielectric layer.

Optionally, in the first direction, the length of the first gate part is smaller than the length of the second gate part, a side of the first gate part is retracted relative to a side of the second gate part, and the thickness of the first dielectric layer is greater than the thickness of the second dielectric layer.

A method for manufacturing any of the above-mentioned gate-all-around transistors is provided according to a second aspect of the present disclosure, the method comprises: providing a semiconductor substrate; forming a fin-shaped protrusion, a source, a drain and a gate on a surface of the semiconductor substrate on one side; where the source and the drain are arranged on a top surface of the fin-shaped protrusion, respectively; the gate comprises a first gate part and a second gate part; the first gate part being located on the top surface of the fin-shaped protrusion between the source and the drain; the second gate part being located on a surface of the first gate part on the side away from the fin-shaped protrusion; a first dielectric layer is located on two opposite sides of the first gate part in a first direction; a second dielectric layer is located on two opposite sides of the second gate part in the first direction; the first direction is parallel to a direction of connecting the source and the drain; a dielectric constant of the first dielectric layer is greater than a dielectric constant of the second dielectric layer.

Optionally, forming the fin-shaped protrusion, the source, the drain and the gate on the surface of the semiconductor substrate comprises: forming a stacked structure on the surface of the semiconductor substrate, where the stacked structure comprises a first semiconductor layer and a second semiconductor layer alternately stacked in a second direction; forming a first groove and a second groove penetrating through the stacked structure and extending into the semiconductor substrate, the semiconductor substrate retained between the first groove and the second groove is configured as the fin-shaped protrusion; a remaining stacked structure on a surface of the fin-shaped protrusion is configured as a fin-shaped semiconductor structure; forming the source, the drain and the gate based on the fin-shaped semiconductor structure.

Optionally, forming the source, the drain and the gate based on the fin-type semiconductor structure comprises: forming a dummy gate in a central region of the top surface of the fin-type semiconductor structure, where the dummy gate exposes a portion of the fin-type semiconductor structure corresponding to a source region and a drain region of the gate-all-around transistor; forming the second dielectric layer on a side of the dummy gate; removing the portion of the fin-type semiconductor structure corresponding to the source region and the drain region, and retaining the portion of the fin-type semiconductor structure covered by the dummy gate and the second dielectric layer; etching the remaining fin-type semiconductor structure so that a side of the second semiconductor layer is retracted relative to a side of the first semiconductor layer to form a groove; after the first dielectric layer is formed in the groove, forming a source in the source region and forming a drain in the drain region; after the dummy gate and the second semiconductor layer are removed, filling the dummy gate region and the second semiconductor layer region with a metal material to form the first gate part and the second gate part.

Optionally, the method further comprises: after the dummy gate and the second semiconductor layer are removed, and before filling the metal material, forming a gate dielectric layer on a surface of the groove formed by removing the dummy gate and a surface of the groove formed by removing the second semiconductor layer; where the dielectric constant of the gate dielectric layer is greater than the dielectric constant of the second dielectric layer.

By means of the above aspects of the present disclosure, in the gate-all-around transistor and the method for manufacturing the gate-all-around transistor according to embodiments of the present disclosure, since the dielectric layer with a high dielectric constant has good process stability and thermal performance, a first dielectric layer with a high dielectric constant is arranged on the side of the first gate part, and the process stability of the first dielectric layer can be guaranteed upon the forming of the first gate part. Since the parasitic capacitance formed by the dielectric layer with a low dielectric constant is small, a second dielectric layer with a low dielectric constant is arranged on the side of the second gate part, which can reduce the parasitic capacitance of the gate in the second gate part. The technical solutions of the present disclosure can reduce the parasitic capacitance while maintaining the process stability of the first dielectric layer by means of the first dielectric layer and the second dielectric layer with different dielectric constants.

### BRIEF DESCRIPTION OF THE DRAWINGS

In order to illustrate the technical solutions in the embodiments or related technologies of the present disclosure clearly, drawings required for use in the descriptions for the embodiments or the conventional technology are briefly introduced as follows. Apparently, drawings described below are only used for illustrating embodiments of the present disclosure. For those skilled in the art, other drawings can be obtained based on the provided drawings without creative work.

The structures, proportions, sizes, or the like shown in the drawings of this specification are only intended for acknowledgement and understanding by those persons familiar with the present technology in connection with the contents disclosed in the present specification, and are not intended to define the limitation conditions under which the present disclosure can be implemented. Therefore, they have no technical substantive significance. Any modification to the structures, change to the proportions or adjustment to the sizes would fall within the scope of the technical content disclosed in the present disclosure as long as the effects and purposes that can be achieved by the present disclosure are not influenced.

FIG. 1 is a schematic diagram of a three-dimensional structure of a gate-all-around transistor according to an embodiment of the present disclosure.

FIG. 2 is a cross-sectional view of the gate-all-around transistor shown in FIG. 1 in the A-A′ direction.

FIG. 3 is a cross-sectional view of the gate-all-around transistor shown in FIG. 1 in the B-B′ direction.

FIG. 4 is a cross-sectional view of a gate-all-around transistor according to an embodiment of the present disclosure in a direction parallel to a length of a fin-shaped protrusion of the gate-all-around transistor.

FIG. 5 is a cross-sectional view of a gate-all-around transistor according to another embodiment of the present disclosure in a direction parallel to the length of a fin-shaped protrusion of the gate-all-around transistor.

FIG. 6 is a process flow chart of a method for manufacturing a gate-all-around transistor according to an embodiment of the present disclosure.

FIG. 7 is a flow chart of a method for forming an electrode structure in a gate-all-around transistor according to an embodiment of the present disclosure.

FIG. 8 is a flow chart of a method for forming a source, a drain and a gate based on a fin-shaped semiconductor structure according to an embodiment of the present disclosure.

FIG. 9-FIG. 23 are cross-sectional views of a gate-all-around transistor in different process steps of a method for manufacturing the gate-all-around transistor according to an embodiment of the present disclosure.

### REFERENCE NUMERALS

11: semiconductor substrate; 111: fin-shaped protrusion;
12: source; 13: drain; 14: gate; 141: first gate part; 142: second gate part; 15: first dielectric layer; 16: second dielectric layer; 17: gate block; 18: first semiconductor layer; 19: gate dielectric layer; 20: shallow groove isolation; 21: insulating layer; 22: second semiconductor layer; 23: mask layer; 24: amorphous silicon; 25: oxide layer; 26: first groove; 27: second groove; 28: dummy gate.

### DETAILED DESCRIPTION OF EMBODIMENTS

Embodiments in the present disclosure will be described clearly and completely as below in connection with the drawings in the embodiments of the present disclosure. It is known to those skilled in the art that, with the development of technology and the emergence of new scenarios, the technical solutions according to the embodiments of the present disclosure are also applicable to similar technical problems.

Apparently, the described embodiments are only a part of the embodiments of the present disclosure, rather than all of the embodiments of the present disclosure. Based on the embodiments in the present disclosure, all other embodiments obtained by those skilled in the art without creative work are within the scope of protection of the present disclosure. The terms used in the embodiments of the present disclosure are only used to explain the specific embodiments of the present disclosure, and are not intended to limit the present disclosure.

In order to make the above-mentioned purposes, features and advantages of the present disclosure more apparent, the present disclosure is further described in detail in connection with the drawings and specific embodiments.

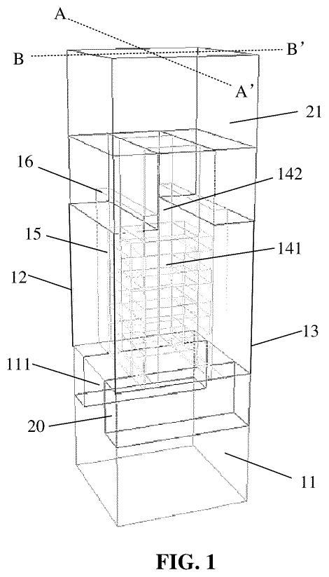

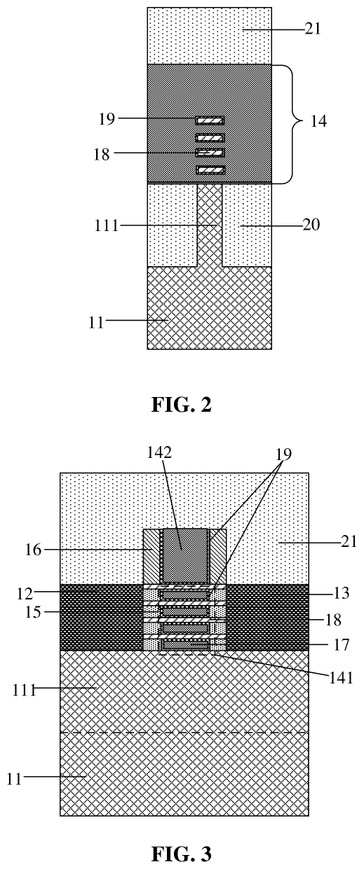

Reference is made to FIGS. 1-3. FIG. 1 is a schematic diagram of a three-dimensional structure of a gate-all-around transistor according to an embodiment of the present disclosure. FIG. 2 is a cross-sectional view of the gate-all-around transistor shown in FIG. 1 in the A-A′ direction, and FIG. 3 is a cross-sectional view of the gate-all-around transistor shown in FIG. 1 in the B-B′ direction. The gate-all-around transistor shown in FIGS. 1-3 includes: a semiconductor substrate 11, where a fin-shaped protrusion 111 is provided at a surface of the semiconductor substrate 11 on one side; a source 12 and a drain 13 respectively arranged on a top surface of the fin-shaped protrusion 111; a gate 14 including a first gate part 141 and a second gate part 142, where the first gate part 141 is located on the top surface of the fin-shaped protrusion 111 between the source 12 and the drain 13, the second gate part 142 is located on a surface of the first gate part 141 on the side away from the fin-shaped protrusion 111; a first dielectric layer 15 located on two opposite sides of the first gate part 141 in a first direction; a second dielectric layer 16 located on two opposite sides of the second gate part 142 in the first direction; where, the first direction is parallel to a direction of connecting the source 12 and the drain 13; a dielectric constant of the first dielectric layer 15 is greater than that of the second dielectric layer 16.

The first direction is the horizontal direction in FIG. 3, that is, the B-B′ direction in FIG. 1. The cross section of the cross-sectional view shown in FIG. 2 is parallel to the A-A direction, and is perpendicular to the length direction of the fin-shaped protrusion 111. The cross section of the cross-sectional view shown in FIG. 3 is parallel to the B-B′ direction, and is parallel to the length direction of the fin-shaped protrusion.

In the gate-all-around transistor according to the embodiment of the present disclosure, the dielectric layer with a high dielectric constant has good process stability and thermal performance, so a first dielectric layer 15 with a high dielectric constant is provided on the side of the first gate part 141, such that the process stability of the first dielectric layer 15 can be guaranteed when the first gate part 141 is formed. Since a parasitic capacitance formed by the dielectric layer with a low dielectric constant is small, a second dielectric layer 16 with a low dielectric constant is provided on the side of the second gate part 142, such that the parasitic capacitance of the gate 14 in the second gate part 142 can be reduced. In the technical solution of the present disclosure, the parasitic capacitance of the gate 14 can be reduced while the process stability of the first dielectric layer 15 is maintained, with the first dielectric layer 15 and the second dielectric layer 16 with different dielectric constants.

Optionally, the first dielectric layer 15 is a high-K material, and the second dielectric layer 16 is a low-K material. K is the relative dielectric constant, which is equal to the ratio of the absolute dielectric constant of the dielectric material to the dielectric constant of the vacuum. The K value of the high-K material is greater than 3.9, and the K value of the low-K material is not greater than 3.9.

Since the first dielectric layer 15 is the high-K material, the process stability of the first dielectric layer 15 can be better ensured when the first gate part 141 is formed. Since the second dielectric layer 16 is the low-K material, the parasitic capacitance of the gate 14 in the second gate part 142 can be better reduced.

Optionally, the first gate part 141 includes a plurality of gate blocks 17 stacked in sequence in a second direction parallel to the height direction of the fin-shaped protrusion 111, that is, the second direction is the vertical direction in FIG. 3. A first semiconductor layer 18 is disposed between adjacent gate blocks 17. Two opposite sides of the first semiconductor layer 18 in the first direction contact the source 12 and the drain 13, respectively. The gate block 17 is spaced apart from both the source 12 and the drain 13 for receiving the first dielectric layer 15.

In the gate-all-around transistor according to the embodiment of the present disclosure, the first gate part 141 adopts a stacked structure of multiple gate blocks 17, which can improve the performance and integration of the gate-all-around transistor. With this design. not only a control capability of the gate over a channel in the gate-all-around transistor is enhanced, but also static power consumption is effectively reduced, while allowing the size of the gate-all-around transistor to be further reducted.

In an embodiment of the present disclosure, a gate dielectric layer 19 is disposed between the gate block 17 and the first semiconductor layer 18 and between the gate block 17 and the first dielectric layer 15. The gate dielectric layer 19 is also disposed between the second gate part 142 and the second dielectric layer 16. The dielectric constant of the gate dielectric layer is greater than that of the second dielectric layer.

Optionally, the dielectric constant of the gate dielectric layer 19 is greater than that of the first dielectric layer 15. The gate dielectric layer 19 with a higher dielectric constant can enhance the control efficiency of the gate the gate-all-around transistor and reduce the leakage current of the gate-all-around transistor. The gate dielectric layer 19 with the higher dielectric constant can also provide a better electrical isolation effect for the gate of the gate-all-around transistor and protect the material of the gate of the gate-all-around transistor. Therefore, with the gate dielectric layer 19 with the higher dielectric constant, not only the performance of the gate-all-around transistor can be improved, but also the reliability and stability of the gate-all-around transistor at a nanometer level can be ensured. In order to better achieve the above effects through the gate dielectric layer 19, the gate dielectric layer 19 is formed of the high-K material.

In an embodiment of the present disclosure, the thickness of the gate dielectric layer 19 is set to be less than that of the first dielectric layer 15, and less than that of the second dielectric layer 16. In this way, the gate dielectric layer 19 can have a smaller thickness compared with the first dielectric layer 15 and the second dielectric layer 16. The gate dielectric layer 19 with the smaller thickness can have a good compactness, so that the above effects can be better achieved through the gate dielectric layer 19. In addition, for a certain size of the gate-all-around transistor, due to the gate dielectric layer 19 with the smaller thickness, a first dielectric layer 15 and a second dielectric layer 16 with sufficient thicknesses can be form, so as to better reduce parasitic capacitance and ensure process stability.

Optionally, the multiple gate blocks 17 in the first gate part 141 have the same length in the first direction, and sides of the gate blocks 17 are aligned from each other in the second direction, so as to facilitate processes for manufacturing the multiple gate blocks 17 in the first gate part 141.

In one example of the embodiment of the present disclosure, as shown in FIG. 3, the first gate part 141 and the second gate part 142 have the same length in the first direction. Sides of the first gate part 141 and the second gate part 142 are aligned from each other in the second direction. The first dielectric layer 15 and the second dielectric layer 16 have the same thickness. Each gate block 17 in the first gate part 141 and the second gate part 142 have the same length in the first direction. Sides of each gate block 17 in the first gate part 141 and the second gate part 142 are aligned from each other in the second direction. Therefore, the first dielectric layer 15 and the second dielectric layer 16 have the same thickness, in order to facilitate processes for manufacturing the gate-all-around transistor.

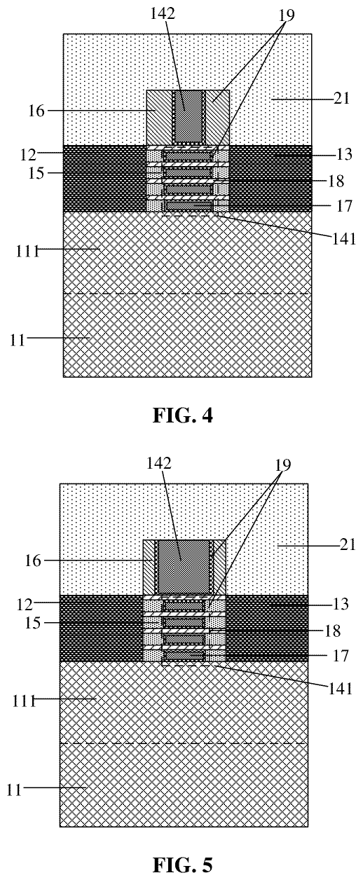

In other embodiments, in order to better adjust the process stability of the dielectric layer during the manufacturing of the gate-all-around transistor and better reduce the parasitic capacitance of the gate-all-around transistor, the first gate part 141 and the second gate part 142 can have different lengths in the first direction, sides of the first gate part and the second gate part are not aligned from each other in the second direction, and the first dielectric layer 15 and the second dielectric layer 16 have different thickness. The gate-all-around transistor can have the structure as shown in FIG. 4 or FIG. 5.

Reference is made to FIG. 4. FIG. 4 is a cross-sectional view of a gate-all-around transistor according to an embodiment of the present disclosure in a direction parallel to the length of a fin-shaped protrusion of the gate-all-around transistor. The gate-all-around transistor as shown in FIG. 4 is different from the gate-all-around transistor as shown in FIG. 3 in that, in the first direction, the length of the first gate part 141 is greater than the length of the second gate part 142, a side of the second gate part 142 is retracted relative to a side of the first gate part 141, and the thickness of the first dielectric layer 15 is less than the thickness of the second dielectric layer 16.

Reference is made to FIG. 5. FIG. 5 is a cross-sectional view of a gate-all-around transistor according to an embodiment of the present disclosure in a direction parallel to the length of a fin-shaped protrusion of the gate-all-around transistor. The gate-all-around transistor as shown in FIG. 5 is different from the gate-all-around transistor as shown in FIG. 3 in that, in the first direction, the length of the first gate part 141 is less than the length of the second gate part 142, a side of the first gate part 141 is retracted relative to a side of the second gate part 142, and the thickness of the first dielectric layer 15 is greater than the thickness of the second dielectric layer 16.

In the gate-all-around transistors as shown in FIG. 4 and FIG. 5, for a certain size of the gate-all-around transistor, the process stability and parasitic capacitance of the dielectric layer in the gate-all-around transistor can be adjusted through adjusting the lengths of the first gate part 141 and the second gate part 142 and the thicknesses of the first dielectric layer 15 and the second dielectric layer 16, so as to achieve a well tradeoff between the process stability and the low parasitic capacitance of the dielectric layer.

In an embodiment of the present disclosure, the first dielectric layer 15 as an inner side wall surrounding a material of the gate of the gate-all-around transistor, has a high dielectric constant, which can achieve more effective gate control capability and reduced leakage. The second dielectric layer 16, as the outer side wall of the material of the gate, has a function of protecting and supporting the inner wall and the gate, and thus the damage of the subsequent processing steps to the inner side wall and the gate 14 can be avoided.

At present, the gate-all-around transistor has challenges of complex process for manufacturing the inner side wall and large parasitic capacitance and resistance. The Large parasitic capacitance is the main issue that limits the circuit operating speed and the application of the gate-all-around transistor. The root cause of the large parasitic capacitance of the gate-all-around transistor is that the nanosheet stacking structure causes the overlapping area between the gate 14 and the source and the drain increases. Accordingly, the gate-source parasitic capacitance Cgs and the gate-drain parasitic capacitance Cgd increase to become the dominant factor, which seriously affects the circuit operating speed. In the nanosheet (NS) gate-all-around transistor structure, the width and the material of the inner and outer sidewalls at the overlapping area between the gate 14 and the source 12 and drain 13 are main factors affecting the gate-source parasitic capacitance Cgs and the gate-drain parasitic capacitance Cgd. In conventional gate-all-around transistors, the inner and outer sidewall have the same material such as Si₃N₄ with a K value of about 7 due to good process stability. However, this large K value will lead to a large parasitic capacitance. Although the parasitic capacitance can be reduced in a case that both the inner and outer sidewalls are formed from a sidewall with a low-K material or an air sidewall, there are problems such as poor process stability and unstable thermal performance during process integration and process processing, and the requirements to the material for the complex preparation process of the inner sidewall cannot be met.

In the gate-all-around transistor according to the embodiment of the present disclosure, the first dielectric layer 15 and the second dielectric layer 16 have different dielectric constants, and the dielectric constant of the first dielectric layer 15 is greater than the dielectric constant of the second dielectric layer 16, thereby forming a novel gate-all-around transistor having a sidewall structure with two different K values. The first dielectric layer 15 as the inner sidewall has a high-K material with good stability (including, but not limited to, Si₃N₄), and the second dielectric layer 16 as the outer sidewall has a low-K material.

By making the first dielectric layer 15 and the second dielectric layer 16 having materials with different dielectric constants, the dielectric constants of the first dielectric layer 15 and the second dielectric layer 16 and a ratio of the widths of the first dielectric layer 15 and the second dielectric layer 16 in the first direction can be adjusted independently, so that the parasitic capacitance of the NS gate-all-around transistor can be significantly reduced while maintaining the process stability of the inner sidewall.

The first semiconductor layer 18 is a nanosheet as a channel of the gate-all-around transistor. The width of the nanosheet may be 5 nm˜50 nm, and the thickness of the nanosheet may be 3 nm˜20 nm. The width of the nanosheet is the size of the first semiconductor layer 18 in the horizontal direction of FIG. 2, that is, the size of the first semiconductor layer 18 in the width direction of the fin-shaped protrusion 111. The thickness of the nanosheet is the size of the first semiconductor layer 18 in the vertical direction of FIGS. 2 and 3, that is, the size the first semiconductor layer 18 in the height direction of the fin-shaped protrusion 111. The material of the first semiconductor layer 18 may be SiGe.

In the width direction of the fin-shaped protrusion 111, two opposite sides of the fin-shaped protrusion 111 are respectively provided with a first groove and a second groove to form the fin-shaped protrusion 111 on the surface of the semiconductor substrate 11. The first groove and the second groove are filled with an insulating material to form a shallow groove isolation 20, and the insulating material may be silicon oxide. The top surfaces of the gate 14 and the source and the drain are covered with an insulating layer 21. The insulating layer 21 may be silicon oxide.

In an embodiment of the present disclosure, the gate-all-around transistor may be configured as a NOMS structure or a PMOS structure.

In a case that the gate-all-around transistor is configured as the NMOS structure, the semiconductor substrate 11 may be P-type doped, for example, the semiconductor substrate 11 may be configured as a P-type Si substrate; the source 12 and the drain 13 may be N-type doped, for example, the source 12 and the drain 13 may be configured as a phosphorus-doped N-type Si material.

In a case that the gate-all-around transistor is configured as the PMOS structure, the semiconductor substrate 11 may be N-type doped, for example, the semiconductor substrate 11 may be configured as an N-type Si substrate; the source 12 and the drain 13 may be P-type doped, for example, the source 12 and the drain 13 may be configured as a boron-doped P-type SiGe material.

In an embodiment of the present disclosure, the thicknesses of the first dielectric layer 15 and the second dielectric layer 16 in the first direction may be set as necessary, and the thicknesses of the first dielectric layer 15 and the second dielectric layer 16 in the first direction may be same or different, so as to flexibly adjust the thickness of the first dielectric layer 15 and the second dielectric layer 16 in the first direction as necessary, thereby adjusting the process stability and parasitic capacitance.

Based on the gate-all-around transistor in the above embodiment, another embodiment of the present disclosure provides a method for manufacturing the above gate-all-around transistor. This method can be shown in FIG. 6.

Reference is made to FIG. 6. FIG. 6 is a process flow chart of a method for manufacturing a gate-all-around transistor provided in the embodiment of the present disclosure. With reference to the drawings of the gate-all-around transistor in the above embodiments and FIG. 6, the method may comprise:
Step S11: providing a semiconductor substrate 11.
Step S12: forming a fin-shaped protrusion 111, a source 12, a drain 13 and a gate 14 on a surface of the semiconductor substrate 11 on one side.

The source 12 and the drain 13 may be respectively arranged on a top surface of the fin-shaped protrusion 111. The gate 14 may include a first gate part 141 and a second gate part 142. The first gate part 141 may be located on the top surface of the fin-shaped protrusion 111 between the source 12 and the drain 13. The second gate part 142 may be located on a surface of the first gate part 141 on the side away from the fin-shaped protrusion 111. A first dielectric layer 15 may be disposed on two opposite sides of the first gate part 141 in a first direction. A second dielectric layer 16 may be disposed on two opposite sides of the second gate part 142 in the first direction. The first direction is parallel to the direction of connecting the source 12 and the drain 13. The dielectric constant of the first dielectric layer 15 is greater than the dielectric constant of the second dielectric layer 16.

The method according to the embodiment of the present disclosure can be used to manufacture the gate-all-around transistor according to any of the above embodiments. The process stability of the gate-all-around transistor can be ensured while the parasitic capacitance of the gate-all-around transistor is reduced.

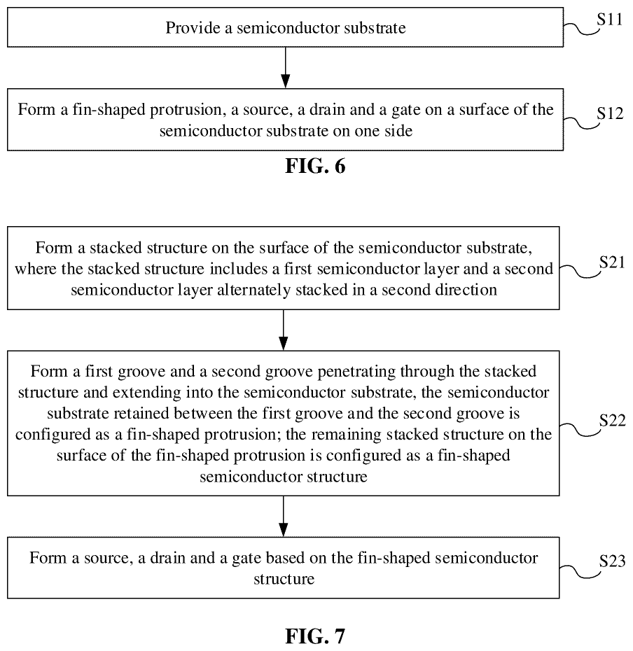

In the method according to the embodiment of the present disclosure, the step of forming the fin-shaped protrusion, the source, the drain and the gate on the one side of the semiconductor substrate is shown in FIG. 7.

Reference is made to FIG. 7. FIG. 7 is a flow chart of a method for forming an electrode structure in a gate-all-around transistor according to an embodiment of the present disclosure. With reference to the drawings of the gate-all-around transistor in the above embodiments and FIG. 7, the method may comprise:
Step S21: forming a stacked structure on a surface of a semiconductor substrate 11, where the stacked structure may include a first semiconductor layer 18 and a second semiconductor layer alternately stacked in a second direction.
Step S22: forming a first groove and a second groove, where the first groove and the second groove penetrate through the stacked structure and extend into the semiconductor substrate 11. The semiconductor substrate 11 retained between the first groove and the second groove may be configured as a fin-shaped protrusion 111. The remaining stacked structure on the surface of the fin-shaped protrusion 111 may be configured as a fin-shaped semiconductor structure.
Step S23: with the fin-shaped semiconductor structure, forming a source 12, a drain 13 and a gate 14.

The second semiconductor layer is configured as a sacrificial layer to form a gate block 17 in the first gate part 141. The gate block 17 may be formed with multiple stacks. The first semiconductor layer 18 may be alternately stacked with the gate block 17 so as to form a channel, which is a nanosheet structure of the gate-all-around transistor.

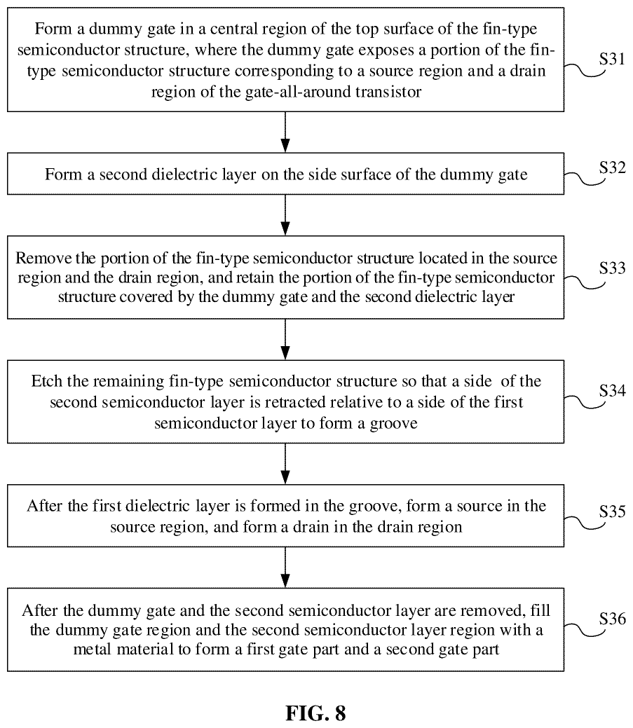

In the method according to the embodiment of the present disclosure, a method for forming the source 12, the drain 13 and the gate 14 with the fin-type semiconductor structure may be as shown in FIG. 8.

Reference is made to FIG. 8. FIG. 8 is a flow chart of a method for forming a source, a drain and a gate with a fin-type semiconductor structure according to an embodiment of the present disclosure. With reference to the drawings of the gate-all-around transistor of the above embodiment and FIG. 8, the method may comprise:
Step S31: forming a dummy gate in the central region of the top surface of the fin-type semiconductor structure, where the dummy gate exposes a portion of the fin-type semiconductor structure corresponding to a source region and a drain region.
Step S32: forming a second dielectric layer 16 on a side of the dummy gate.
Step S33: removing the portion of the fin-type semiconductor structure located in the source region and the drain region, and retaining the portion of the fin-type semiconductor structure covered by the dummy gate and the second dielectric layer 16.
Step S34: etching the remaining fin-type semiconductor structure so that a side of the second semiconductor layer 22 is retracted relative to a side of the first semiconductor layer 18 to form a groove.
Step S35: after the first dielectric layer 15 is formed in the groove, forming a source 12 in the source region, and forming a drain 13 in the drain region.
Step S36: after the dummy gate and the second semiconductor layer is removed, filling the dummy gate region and the second semiconductor layer region with a metal material to form a first gate part 141 and a second gate part 142.

By the method shown in FIG. 8, the dummy gate and the second dielectric layer 16 can be configured as a mask structure for etching the fin-type semiconductor structure to etch the fin-type semiconductor structure so as to form the first dielectric layer 15 and the source and the drain. The dummy gate can also be configured as a sacrificial layer to form the second gate part 142.

Optionally, in the method shown in FIG. 8, after the dummy gate and the second semiconductor layer is removed and before filling the metal material, the method may further comprises: forming a gate dielectric layer 19 on a surface of the groove formed by removing the dummy gate and a surface of the groove formed by removing the second semiconductor layer. The dielectric constant of the gate dielectric layer 19 may be greater than the dielectric constant of the second dielectric layer. The gate dielectric layer 19 can enhance the gate control efficiency of the gate-all-around transistor and reduce the leakage current of the gate transistor. The gate dielectric layer 19 with the high dielectric constant can further provide a better gate electrical isolation effect and protect the gate material. Therefore, the use of the gate dielectric layer 19 with the high dielectric constant can not only improve the performance of the gate-all-around transistor, but also ensure the reliability and stability of the gate-all-around transistor at the nanometer level.

In order to describe a structure of the gate-all-around transistor and the method for manufacturing the gate-all-around transistor more clearly, taking the method for manufacturing the gate-all-around transistor shown in FIGS. 1-3 is taken as an example, and in connection with the cross-sectional views of the gate-all-around transistor in different process steps of the method, the gate-all-around transistor and the method for manufacturing the gate-all-around transistor according to the embodiment of the present disclosure are further described in the following.

Reference is made to FIGS. 9-23. FIGS. 9-23 are cross-sectional views of a gate-all-around transistor in different process steps of the method for manufacturing the gate-all-around transistor according to embodiments of the present disclosure. For each of FIGS. 9-23, the left figure and the right figure respectively represent cross-sectional views of the device in different directions at one process step. For each of FIGS. 9-23, the left figure corresponds to a cross-sectional view cut along a direction perpendicular to the length direction of the fin-shaped protrusion 111, and the right figure corresponds to a cross-sectional view cut along a direction parallel to the length direction of the fin-shaped protrusion 111.

As shown in FIGS. 9-23, the method may comprises:
Step S41: as shown in FIG. 9, providing a semiconductor substrate 11.

For the type of PMOS, the semiconductor substrate 11 may be an N-type doped Si substrate, and for the type of NMOS, the semiconductor substrate 11 may be a P-type doped Si substrate.

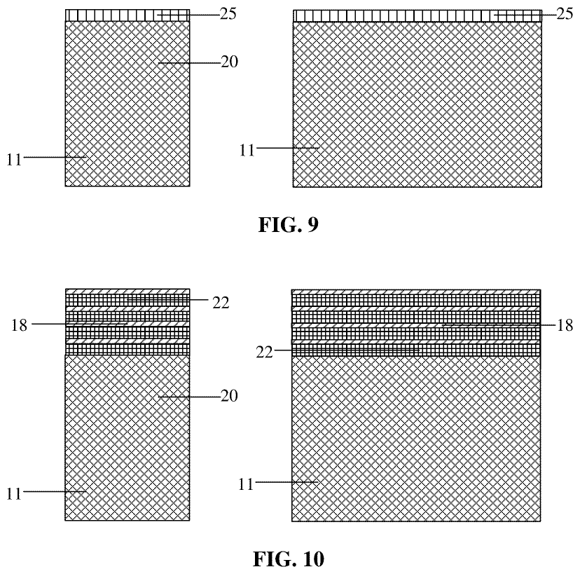

A surface of the semiconductor substrate 11 is easily oxidized and thus the semiconductor substrate 11 has an oxide layer 25, which needs to be removed in the subsequent processes.
Step S42: as shown in FIG. 10, after the surface oxide layer 25 is removed, forming a stacked structure on the surface of the semiconductor substrate 11. The stacked structure may include a first semiconductor layer 18 and a second semiconductor layer 22 alternately disposed in a second direction.

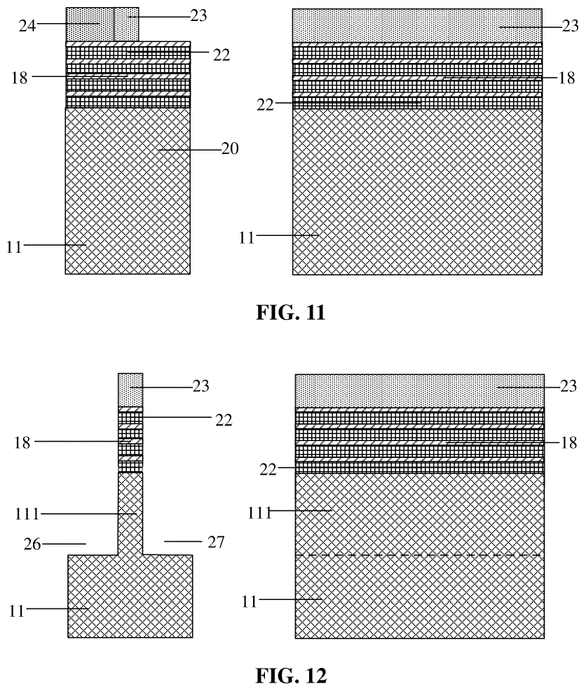

The first semiconductor layer 18 may be SiGe, and the second semiconductor layer 22 may be Si. The stacked structure may be formed by an epitaxial process. The second semiconductor layer 22 may be configured as a sacrificial layer to form a gate block 17 of a gate-all-around transistor. The first semiconductor layer 18 may be configured as a channel of a gate-all-around transistor. The bottom layer of the stacked structure may be configured as the second semiconductor layer 22, and the top layer of the stacked structure may be configured as the first semiconductor layer 18.
Step S43: as shown in FIG. 11, forming a patterned mask layer 23 on a surface of the stacked structure.

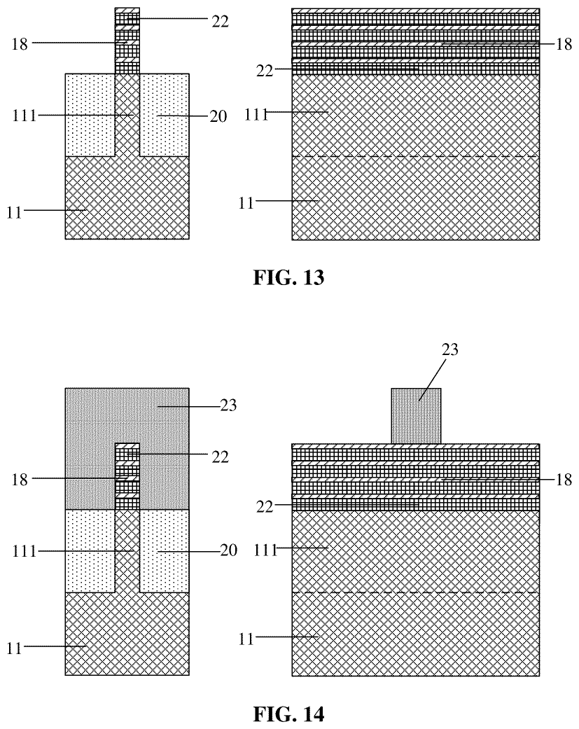

The mask layer 23 may be a SiNx layer. Amorphous silicon 24 may be used as an auxiliary layer to form the mask layer 23 for the desired pattern structure.
Step S44: as shown in FIG. 12, etching on the mask layer 23 to form a first groove 26 and a second groove 27. The semiconductor substrate 11 located between the first groove 26 and the second groove 27 is configured as a fin-shaped protrusion 111. The remaining stacked structure on the top surface of the fin-shaped protrusion 111 is configured as a fin-shaped semiconductor structure. A source 12, a drain 13 and a gate 14 are formed based on the fin-shaped semiconductor structure in the subsequent processes.
Step S45: as shown in FIG. 13, after removing the mask layer 23, filling an insulating material in the first groove 26 and the second groove 27 to form a shallow groove isolation 20. The insulating material may be silicon oxide.
Step S46: as shown in FIG. 14, forming a dummy gate 28. The dummy gate 28 covers at least the central region of the top surface of the fin-shaped semiconductor structure corresponding to the region where the gate 14 is located.

As shown in the right figure in FIG. 14, the dummy gate 28 exposes the source region and drain region of the fin-type semiconductor structure.

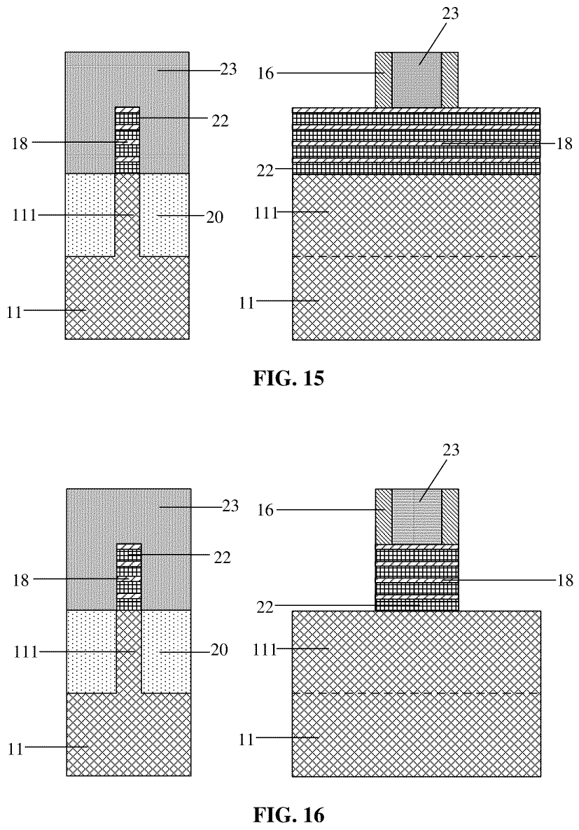

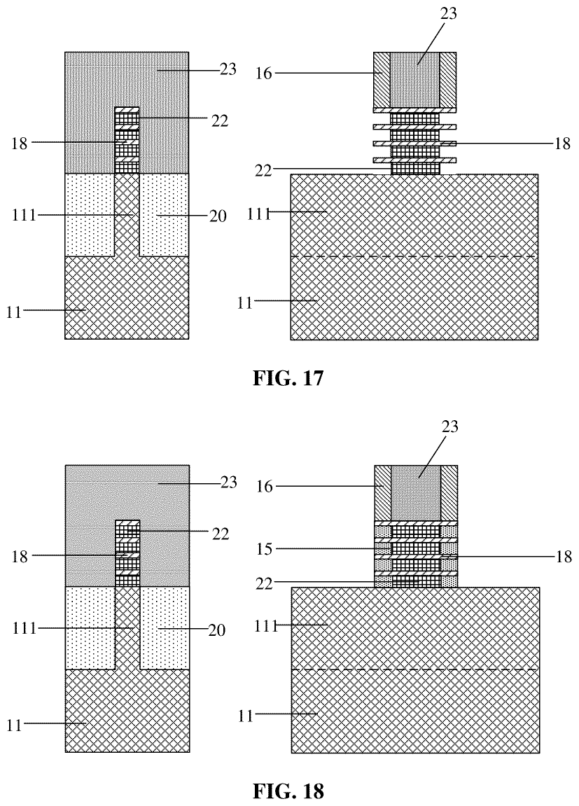

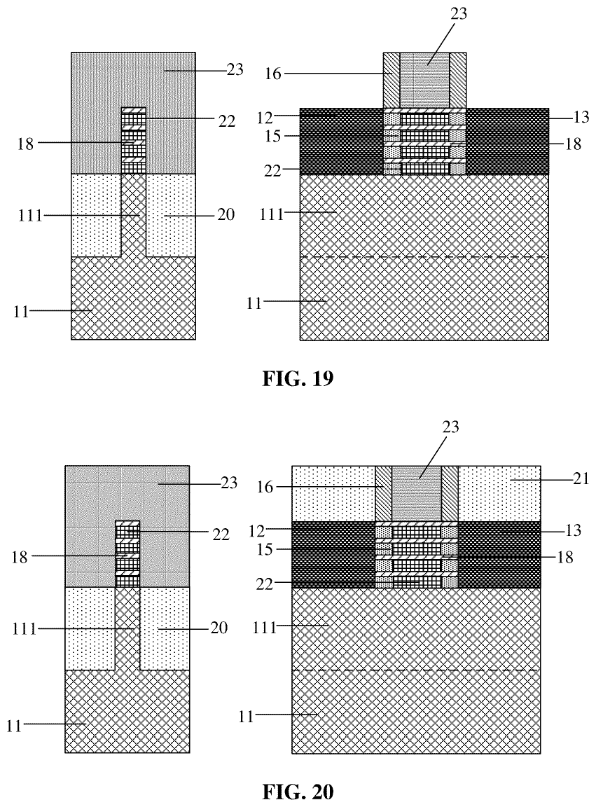

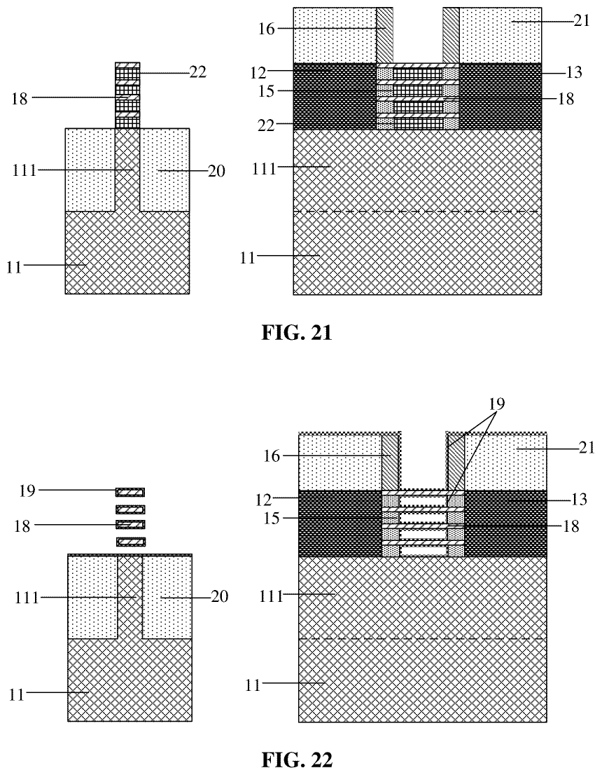

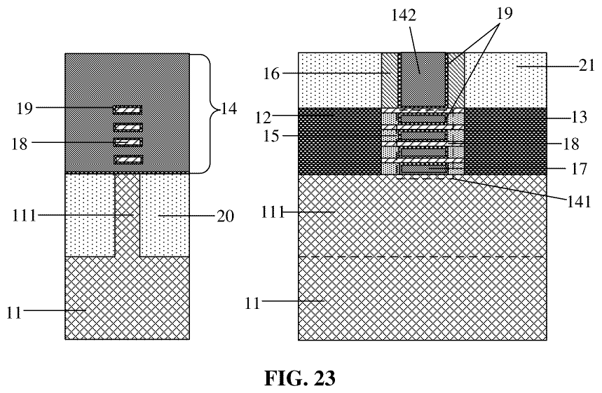

Optionally, the dummy gate 28 may be polycrystalline silicon or amorphous silicon.
Step S47: as shown in FIG. 15, forming a second dielectric layer 16 on the opposite sides of the dummy gate 28 in the first direction. As mentioned above, the second dielectric layer 16 may be a low-K material.
Step S48: as shown in FIG. 16, based on the dummy gate 28 with the second dielectric layer 16 on the opposite sides of the dummy gate 28, etching the fin-type semiconductor structure to remove the fin-type semiconductor structure in the source region and the drain region, and retaining the second dielectric layer 16 and the fin-type semiconductor structure under the dummy gate 28.
Step S49: as shown in FIG. 17, etching the second dielectric layer 16 and the remaining fin-type semiconductor structure under the dummy gate 28 so that a side of the second semiconductor layer 22 is retracted relative to a side of the first semiconductor layer 18 to form a groove.
In step S49, the depth of the groove can be controlled by controlling the lateral etching depth, thereby controlling the thickness of the first dielectric layer 15 formed by the subsequent process in the first direction.
Step S50: as shown in FIG. 18, forming a first dielectric layer 15 based on the groove formed in the previous step. The first dielectric layer 15 may be formed by depositing SiNx material in the groove.
Step S51: as shown in FIG. 19, forming a source 12 and a drain 13 on the top surface of the source region and the drain region of the fin structure. The source 12 and the drain 13 may be formed by an epitaxial process. For the type of PMOS, the source 12 and the drain 13 may be boron-doped SiG. For the type of NMOS, the source 12 and the drain 13 may be phosphorus-doped Si.
Step S52: as shown in FIG. 20, forming an insulating layer 21 on surfaces of the source and the drain. The insulating layer 21 may be configured to surround the second dielectric layer 16.
Step S53: as shown in FIG. 21, removing the dummy gate 28.
Step S54: as shown in FIG. 22, after the second semiconductor layer 22 is removed, forming a gate dielectric layer 19 on a surface of the groove formed by removing the dummy gate 28 and on a surface of the groove formed by removing the second semiconductor layer 22. The gate dielectric layer 19 is a high-K material, such as HfO₂.
Step S55: as shown in FIG. 23, forming a gate 14 through depositing metal in the groove. The metal deposited in this step may fill the groove formed after the second semiconductor layer is removed, so as to form the gate block 17 of the first gate part 141, and may also fill the groove formed after the dummy gate 28 is removed, so as to form the second gate part 142. After the metal is deposited, the metal layer on the surface of the insulating layer 21 is removed through grinding by the CMP process.

Finally, another insulating layer 21 covering the gate 14 is further formed on the surface of the insulating layer 21 to form a gate-all-around transistor with the structure shown in FIG. 2 and FIG. 3.

The method according to embodiments of the present disclosure can prepare the gate-all-around transistor according to the above embodiment to form a novel gate-all-around transistor having a sidewall structure with two different K values, which can significantly reduce the parasitic capacitance and improve the circuit operating speed while ensuring the process stability.

The second dielectric layer 16 is made of a low-K material. After the etching process for the source and the drain shown in FIG. 16 and the etching process for the second semiconductor layer 22 shown in FIG. 17 are completed, the first dielectric layer 15 may be formed using a high-K material with high stability, which can enlarge a process window for the complex inner wall shielding process and improve the yield of the final device and circuit.

In addition, since the steps for forming the first dielectric layer 15 as the inner wall and the second dielectric layer 16 as the outer wall are independent, the thicknesses of the first dielectric layer 15 and the second dielectric layer 16 in the first direction can be adjusted independently, and the thicknesses of the the first dielectric layer 15 and the second dielectric layer 16 can be different. The thicknesses of the inner wall and the outer wall can be flexibly adjusted according to the performance requirements of the final device and circuit, and the corresponding capacitance of the inner wall can be flexibly adjusted to achieve a well tradeoff between process stability and low parasitic capacitance.

In the specification of this application, each embodiment is described in a sequential manner, a parallel manner, or combination of the two manners. Each embodiment focuses on the differences from other embodiments, and the same and similar parts between the embodiments can refer to each other. The embodiments according to the present disclosure can be combined with each other without contradiction.

It should be noted that in the description of the present disclosure, it should be understood that the description of the drawings and embodiments are illustrative rather than restrictive. The same reference numerals throughout the embodiments of the specification identify the same structure. In addition, for the sake of understanding and ease of description, the drawings may exaggerate the thickness of some layers, films, panels, regions, or the like. It is also understood that when an element such as a layer, film, region, or substrate is referred to as “on” another element, the element may be directly on the other element or there may be an intermediate element. In addition, “on . . . ” refers to positioning an element above or below another element, but does not essentially mean positioning on the upper side of another element according to the direction of gravity.

The terms “upper”, “lower”, “top”, “bottom”, “inside”, “outside”, and the like, indicate an orientation or positional relationship based on the orientation or positional relationship shown in the drawings, which is only for the convenience of describing the present disclosure and simplifying the description, rather than indicating or implying that the device or element referred to must have a specific orientation, be constructed and operated in a specific orientation, and therefore cannot be understood as a limitation on the present disclosure. When a component is considered to be “connected” to another component, it may be directly connected to another component or there may be a centrally arranged component at the same time.

It should also be noted that, relational terms such as first and second, and the like described herein are only configured to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that an article or device including a series of elements includes not only those elements, but also other elements not explicitly listed, or also includes elements inherent to such article or device. In the absence of further restrictions, the elements defined by the sentence “including . . . ” do not exclude the existence of other identical elements in the article or device including the above elements.

The above description of the disclosed embodiments enables professionals in the field to implement or use the present disclosure. Various modifications to these embodiments will be obvious to those skilled in the art, and the general principles defined herein can be implemented in other embodiments without departing from the spirit or scope of the present disclosure. Therefore, the present disclosure will not be limited to the embodiments shown herein, but will cover the widest scope consistent with the principles and novel features disclosed herein.

1. A gate-all-around transistor, comprising:
a semiconductor substrate, wherein a fin-shaped protrusion is provided at a surface of the semiconductor substrate on one side;
a source and a drain arranged on a top surface of the fin-shaped protrusion, respectively;
a gate comprising a first gate part and a second gate part; the first gate part being located on the top surface of the fin-shaped protrusion between the source and the drain; the second gate part being located on a surface of the first gate part on the side away from the fin-shaped protrusion;
a first dielectric layer on two opposite sides of the first gate part in a first direction;
a second dielectric layer on two opposite sides of the second gate part in the first direction;
wherein the first direction is parallel to a direction of connecting the source and the drain; a dielectric constant of the first dielectric layer is greater than a dielectric constant of the second dielectric layer.

2. The gate-all-around transistor according to claim 1, wherein the first gate part comprises a plurality of gate blocks stacked in sequence in a second direction, and the second direction is parallel to a height direction of the fin-shaped protrusion;
the gate-all-around transistor further comprises a first semiconductor layer between adjacent gate blocks; two opposite sides of the first semiconductor layer in the first direction contacts the source and the drain, respectively;
the plurality of gate blocks are spaced apart from both the source and the drain for receiving the first dielectric layer.

3. The gate-all-around transistor according to claim 2, wherein a gate dielectric layer is disposed between the plurality of gate blocks and the first semiconductor layer and between the plurality of gate blocks and the first dielectric layer;
the gate dielectric layer is disposed between the second gate part and the second dielectric layer;
wherein a dielectric constant of the gate dielectric layer is greater than the dielectric constant of the second dielectric layer.

4. The gate-all-around transistor according to claim 3, wherein the dielectric constant of the gate dielectric layer is greater than the dielectric constant of the first dielectric layer.

5. The gate-all-around transistor according to claim 3, wherein a thickness of the gate dielectric layer is smaller than a thickness of the first dielectric layer and smaller than a thickness of the second dielectric layer.

6. The gate-all-around transistor according to claim 1, wherein in the first direction, a length of the first gate part is identical with a length of the second gate part, sides of the first gate part and the second gate part are aligned in the second direction, and the thicknesses of the first dielectric layer is identical with the thicknesses of the second dielectric layer.

7. The gate-all-around transistor according to claim 1, wherein in the first direction, a length of the first gate part is different from a length of the second gate part, sides of the first gate part and the second gate part are not aligned in the second direction, and the thicknesses of the first dielectric layer is different from the thickness of the second dielectric layer.

8. The gate-all-around transistor according to claim 7, wherein in the first direction, the length of the first gate part is greater than the length of the second gate part, the side of the second gate part is retracted relative to the side of the first gate part, and the thickness of the first dielectric layer is less than the thickness of the second dielectric layer.

9. The gate-all-around transistor according to claim 7, wherein in the first direction, the length of the first gate part is smaller than the length of the second gate part, the side of the first gate part is retracted relative to the side of the second gate part, and the thickness of the first dielectric layer is greater than the thickness of the second dielectric layer.

10. A method for manufacturing the gate-all-around transistor according to claim 1, the method comprising:
providing a semiconductor substrate;
forming a fin-shaped protrusion, a source, a drain and a gate on a surface of the semiconductor substrate on one side;
wherein the source and the drain are arranged on a top surface of the fin-shaped protrusion, respectively; the gate comprises a first gate part and a second gate part; the first gate part is located on the top surface of the fin-shaped protrusion between the source and the drain; the second gate part is located on a surface of the first gate part on the side away from the fin-shaped protrusion; a first dielectric layer is located on two opposite sides of the first gate part in a first direction; a second dielectric layer is located on two opposite sides of the second gate part in the first direction; the first direction is parallel to a direction of connecting the source and the drain; a dielectric constant of the first dielectric layer is greater than a dielectric constant of the second dielectric layer.

11. The method according to claim 10, wherein forming the fin-shaped protrusion, the source, the drain and the gate on the surface of the semiconductor substrate comprises:
forming a stacked structure on the surface of the semiconductor substrate, wherein the stacked structure comprises a first semiconductor layer and a second semiconductor layer alternately stacked in a second direction;
forming a first groove and a second groove penetrating through the stacked structure and extending into the semiconductor substrate, the semiconductor substrate retained between the first groove and the second groove is configured as the fin-shaped protrusion; the remaining stacked structure on a surface of the fin-shaped protrusion is configured as a fin-shaped semiconductor structure;
forming the source, the drain and the gate based on the fin-shaped semiconductor structure.

12. The method according to claim 11, wherein forming the source, the drain and the gate based on the fin-type semiconductor structure comprises:
forming a dummy gate in a central region of the top surface of the fin-type semiconductor structure, wherein the dummy gate exposes a portion of the fin-type semiconductor structure corresponding to a source region and a drain region of the gate-all-around transistor;
forming the second dielectric layer on a side of the dummy gate;
removing the portion of the fin-type semiconductor structure corresponding to the source region and the drain region, and retaining the portion of the fin-type semiconductor structure covered by the dummy gate and the second dielectric layer;
etching the remaining fin-type semiconductor structure so that a side of the second semiconductor layer is retracted relative to a side of the first semiconductor layer to form a groove;
after the first dielectric layer is formed in the groove, forming a source in the source region and forming a drain in the drain region;
after the dummy gate and the second semiconductor layer are removed, filling the dummy gate region and the second semiconductor layer region with a metal material to form the first gate part and the second gate part.

13. The method according to claim 12, further comprises: after the dummy gate and the second semiconductor layer are removed, and before filling the metal material,
forming a gate dielectric layer on a surface of the groove formed by removing the dummy gate and a surface of the groove formed by removing the second semiconductor layer;
wherein the dielectric constant of the gate dielectric layer is greater than the dielectric constant of the second dielectric layer.
